(19) United States
(12) Patent Application Publication
(10) Pub. No.: US 2025/0274231 A1
(43) Pub. Date: Aug. 28, 2025

(54) SYSTEM AND METHOD FOR IMPLEMENTING OPTIMIZED RATE RECOVERY AND HARQ COMBINING IN A NETWORK

(71) Applicant: JIO PLATFORMS LIMITED, Ahmedabad (IN)

(72) Inventors: Vinod Kumar SINGH, Navi Mumbai (IN); Abhilash KUMAR, Thane (IN); Harshitha P., Kanakapura (IN)

(73) Assignee: JIO PLATFORMS LIMITED, Ahmedabad (IN)

(21) Appl. No.: 18/878,989

(22) PCT Filed: Jul. 25, 2023
(86) PCT No.: PCT/IB2023/057534

§ 371 Date: Dec. 26, 2024

(30) Foreign Application Priority Data
Jul. 25, 2022 (IN) 202221042563

(51) Int. Cl. H04L 5/00; H04L 1/00

(52) U.S. Cl. CPC H04L 5/0007; H04L 1/0063

(57) ABSTRACT

The present disclosure provides a system and a method for implementing rate recovery in the PUSCH and PDCH bit rate processing chain of network. The system packs log likelihood ratios (LLRs) data in such a way that for each equalized in phase and quadrature (IQ) symbols, a predetermined number of LLRs equal to the modulation order are packed. The system de-interleaves the packed LLRs by reading the most significant bit (MSB) LLRs row wise for the number of columns equal to the modulation order. The system uses a single buffer for de-interleaving, bit-deselection, and filler bit addition stages, thereby reducing memory requirement of the system. The system processes only a predetermined number of LLRs to a HARQ combining stage to optimize memory and reduce latency.

### RESERVATION OF RIGHTS

A portion of the disclosure of this patent document contains material, which is subject to intellectual property rights such as but are not limited to, copyright, design, trademark, integrated circuit (IC) layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### FIELD OF INVENTION

The embodiments of the present disclosure generally relate to systems and methods for processing radio frames in a wireless telecommunication system. More particularly, the present disclosure relates to a system and a method for implementing rate recovery and hybrid automatic repeat request (HARQ) combining in a network.

### BACKGROUND

The following description of the related art is intended to provide background information pertaining to the field of the disclosure. This section may include certain aspects of the art that may be related to various features of the present disclosure. However, it should be appreciated that this section is used only to enhance the understanding of the reader with respect to the present disclosure, and not as admissions of the prior art.

Rate matching at transmitter side is responsible for, bit selection and bit interleaving of the Low Density Parity Check (LDPC) encoded code blocks. The Physical layer performs a Base Graph selection for the LDPC channel coding. This selection is necessary prior to the channel coding itself because the base graph selection determines the maximum code block size and thus impacts the requirement for code block segmentation. The maximum code block size is the maximum number of bits which can be accepted by the LDPC channel encoder. Blocks of data larger than this upper limit must be segmented before channel coding. Channel coding is then applied individually to each code block segment. Restricting the code block size handled by the channel coding algorithm helps to limit the encoding complexity at the user equipment (UE). The Base Graph selection uses a combination of coding rate and transport block size thresholds. The output from the LDPC channel encoder is forwarded to the Rate Matching function.

The Rate Matching function processes each code block separately. Rate Matching is completed in 2 stages namely a bit selection and a bit interleaving process. Bit selection process reduces or repeats the number of channel coded bits to match the capacity of the allocated air-interface resources. Bit selection extracts ‘E’ bits from the LDPC encoded code block bit-stream present in a circular buffer of size N. The size of the circular buffer may have a dependency upon the UE capability as well. Limited Buffer Rate Matching (LBRM) is a feature to cater to devices which have a limited capacity for buffering large code blocks. The bit interleaving stage involves a stream of bits being read into a table row-by-row, and then being read out of the table column-by-column. The number of rows belonging to the table is set equal to a modulation order.

At the receiver end, Rate Recovery and HARQ combining stages of 5G New Radio Physical Downlink Shared Channel (PDSCH) and Physical Uplink Shared Channel (PUSCH) receiver chains are responsible for performing inverse operation of rate matching at the transmitter side. They require Soft bits (called Log Likely-hood Ratios or LLRs) to be buffered in the memory at separate sub-stages namely de-interleaving, de-selection and incremental redundancy based Hybrid automatic repeat request (hybrid ARQ or HARQ) combining. Since each LLR is usually represented in fixed point format with ‘n’ number of bits, memory requirement for processing ‘G’ number of LLRs at any sub-stage will be ‘nG’ bits. Hence, as compared to transmitter, each reciprocal stage at the receiver requires ‘n’ times more memory. Memory is a scarce resource in any system such as Field Programmable Gate Arrays (FPGAs), eASIC or digital signal processor (DSP) chipsets and henceforth need to be allocated wisely.

There is, therefore, a need in the art to provide a system and a method that can mitigate the problems associated with the prior arts.

### OBJECTS OF THE INVENTION

Some of the objects of the present disclosure, which at least one embodiment herein satisfies are listed herein below.

It is an object of the present disclosure to provide a system and a method using an optimized rate recovery and a hybrid automatic repeat request (HARQ) combining method for physical downlink shared channel (PDSCH) and physical uplink shared channel (PUSCH) receiver bit rate processing chain.

It is an object of the present disclosure to use a single buffer for all three rate recovery sub stages namely-de-interleaving, bit-de-selection and filler bit addition stages.

It is an object of the present disclosure to provide a system and a method to de-interleave LLRs received from a de-scrambler in the Rate Recovery module by storing packed LLRs in a buffer row wise and reading out most significant bit (MSB) LLRs across all rows till the limited number of LLR columns have been read out.

It is an object of the present disclosure to provide a system and a method that uses only a finite ‘data length’ number of LLRs during the HARQ combining stage instead of full ‘N’ number of LLRs to reduce latency and power consumption.

It is an object of the present disclosure to provide a system and a method where the data length number of LLRs are based on a start offset based on the base graph and Redundancy Version (RV) index used for a particular code block.

### SUMMARY

This section is provided to introduce certain objects and aspects of the present disclosure in a simplified form that are further described below in the detailed description. This summary is not intended to identify the key features or the scope of the claimed subject matter.

In an aspect, the present disclosure relates to a system for optimized memory utilization during uplink data decoding at a base station. The system includes a processor and a memory operatively coupled to the processor, where the memory stores instructions to be executed by the processor. The processor receives an input from a computing device associated with one or more users. The input is based on one or more orthogonal frequency division multiplexing (OFDM) subcarriers transmitted by the computing device via a physical uplink shared channel (PUSCH). The processor determines in phase and quadrature (IQ) data symbols associated with the one or more OFDM subcarriers. The processor generates one or more log likelihood ratios (LLRs) based on the one or more IQ data symbols. The processor utilizes a predetermined number of LLR data bits associated with the one or more LLR data bits for each of the one or more IQ data symbols for optimized memory utilization.

In an embodiment, the predetermined number of LLR data bits may be based on a start offset derived from a low-density parity check (LDPC) base graph and a redundancy version (RV) index associated with the PUSCH processing.

In an embodiment, the processor may generate a rate recovered output based on the one or more LLR data bits.

In an embodiment, the processor may generate the rate recovered output by storing the LLR data bits row wise in a buffer and streaming out most significant bit (MSB) LLR data bits across all rows till a limited number of LLR columns are streamed, and the limited number of LLR data bits columns may be based on a modulation order of the one or more IQ data symbols.

In an aspect, the present disclosure relates to a method for optimized memory utilization during uplink data decoding at a base station. The method includes receiving, by a processor associated with a system, an input from a computing device associated with one or more users. The input is based on one or more OFDM subcarriers transmitted by the computing device via a PUSCH. The method includes determining, by the processor, one or more IQ data symbols associated with the one or more OFDM subcarriers. The method includes generating, by the processor, one or more LLR data bits based on the one or more IQ data symbols. The method includes utilizing, by the processor, a predetermined number of LLR data bits associated with the one or more LLR data bits for each of the one or more IQ data symbols for optimized memory utilization.

In an embodiment, the predetermined number of LLR data bits is based on a start offset derived from a LDPC base graph and a RV index associated with the PUSCH processing.

In an embodiment, the method may include generating, by the processor, a rate recovered output based on the one or more LLR data bits.

In an embodiment, the method may include generating, by the processor, the rate recovered output by storing the LLR data bits row wise in a buffer and streaming out MSB LLR data bits across all rows till a limited number of LLR columns are streamed, and the limited number of LLR data bits columns may be based on a modulation order of the one or more IQ data symbols.

In an aspect, a non-transitory computer readable medium includes a processor with executable instructions that cause the processor to receive an input from a computing device associated with one or more users. The input is based on one or more OFDM subcarriers transmitted by the computing device via a PUSCH. The processor determines one or more in IQ data symbols associated with the one or more OFDM subcarriers. The processor generates one or more LLR data bits based on the one or more IQ data symbols. The processor utilizes a predetermined number of LLR data bits associated with the one or more LLR data bits for each of the one or more IQ data symbols for optimized memory utilization.

In an aspect, the present disclosure relates to a user equipment (UE) for optimized memory utilization. The UE includes a processor and a memory operatively coupled to the processor, where the memory stores instructions to be executed by the processor. The processor receives an input from a base station associated with one or more users. The input is based on one or more OFDM subcarriers received by the computing device via a physical downlink shared channel (PDSCH). The processor determines one or more IQ data symbols associated with the one or more OFDM subcarriers. The processor generates one or more LLRs based on the one or more IQ data symbols. The processor utilizes a predetermined number of LLR data bits associated with the one or more LLR data bits for each of the one or more IQ data symbols for optimized memory utilization.

In an embodiment, the predetermined number of LLR data bits is based on a start offset derived from a LDPC base graph and a RV index associated with the PDSCH processing.

In an embodiment, the processor may generate a rate recovered output based on the one or more LLR data bits.

In an embodiment, the processor may generate the rate recovered output by storing the LLR data bits row wise in a buffer and streaming out MSB LLR data bits across all rows till a limited number of LLR columns are streamed, and the limited number of LLR data bits columns may be based on a modulation order of the one or more IQ data symbols.

In an aspect, the present disclosure relates to a method for optimized memory utilization during downlink data decoding at a UE. The method includes receiving, by a processor associated with a system, an input from a base station associated with one or more users. The input is based on one or more OFDM subcarriers received by the UE via a PDSCH. The method includes determining, by the processor, one or more IQ data symbols associated with the one or more OFDM subcarriers. The method includes generating, by the processor, one or more LLR data bits based on the one or more IQ data symbols. The method includes utilizing, by the processor, a predetermined number of LLR data bits associated with the one or more LLR data bits for each of the one or more IQ data symbols for optimized memory utilization.

### BRIEF DESCRIPTION OF DRAWINGS

The accompanying drawings, which are incorporated herein, and constitute a part of this disclosure, illustrate exemplary embodiments of the disclosed methods and systems which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components, or circuitry commonly used to implement such components.

FIG. 1 illustrates an example network architecture (100) for implementing a proposed system (108), in accordance with an embodiment of the present disclosure.

FIG. 2 illustrates an example block diagram (200) of a proposed system (108), in accordance with an embodiment of the present disclosure.

FIG. 3 illustrates an example block diagram (300) of a base graph selection during channel coding, in accordance with an embodiment of the present disclosure.

FIG. 4 illustrates an example block diagram (400) of a bit selection process, in accordance with an embodiment of the present disclosure.

FIG. 5 illustrates an example architecture diagram (500) of bit rate processing in a physical uplink shared channel (PUSCH) receiver with optimized rate recovery and hybrid automatic repeat request (HARQ) combining, in accordance with an embodiment of the present disclosure.

FIG. 6 illustrates an example block diagram (400) of a bit selection process of the PUSCH receiver incorporating optimized rate recovery and HARQ combining, in accordance with an embodiment of the present disclosure.

FIG. 7 illustrates an example block diagram (700) of the HARQ buffer, in accordance with an embodiment of the present disclosure.

FIG. 8 illustrates an example computer system (800) in which or with which embodiments of the present disclosure may be implemented.

The foregoing shall be more apparent from the following more detailed description of the disclosure.

### DETAILED DESCRIPTION

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail to avoid obscuring the embodiments.

Also, it is noted that individual embodiments may be described as a process that is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive in a manner similar to the term “comprising” as an open transition word without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an”, and “the” are intended to include the plural forms as well, unless the context indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

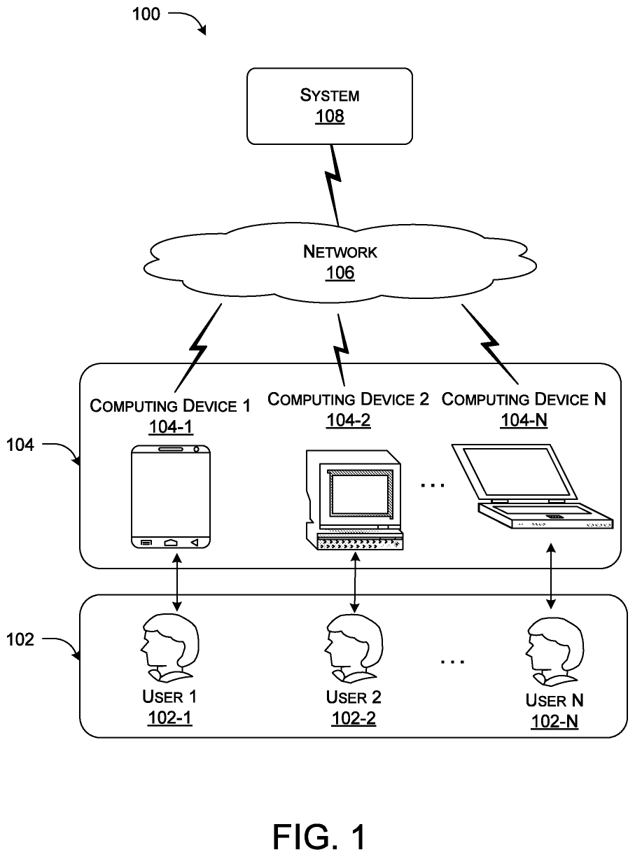

The various embodiments throughout the disclosure will be explained in more detail with reference to FIGS. 1-8.

FIG. 1 illustrates an example network architecture (100) for implementing a proposed system (108), in accordance with an embodiment of the present disclosure.

As illustrated in FIG. 1, the network architecture (100) may include a system (108). The system (108) may be connected to one or more computing devices (104-1, 104-2 . . . 104-N) via a network (106). The one or more computing devices (104-1, 104-2 . . . 104-N) may be interchangeably specified as a user equipment (UE) (104) and be operated by one or more users (102-1, 102-2 . . . 102-N). Further, the one or more users (102-1, 102-2 . . . 102-N) may be interchangeably referred as a user (102) or users (102). In an embodiment, the computing devices (104) may be connected to a base station (110) via the network (106). Further, the system (108) may also be connected to the base station (110).

In an embodiment, the computing devices (104) may include, but not be limited to, a mobile, a laptop, etc. Further, the computing devices (104) may include a smartphone, virtual reality (VR) devices, augmented reality (AR) devices, a general-purpose computer, desktop, personal digital assistant, tablet computer, and a mainframe computer. Additionally, input devices for receiving input from the user (102) such as a touch pad, touch-enabled screen, electronic pen, and the like may be used. A person of ordinary skill in the art will appreciate that the computing devices (104) may not be restricted to the mentioned devices and various other devices may be used.

In an embodiment, the network (106) may include, by way of example but not limitation, at least a portion of one or more networks having one or more nodes that transmit, receive, forward, generate, buffer, store, route, switch, process, or a combination thereof, etc. one or more messages, packets, signals, waves, voltage or current levels, some combination thereof, or so forth. The network (106) may also include, by way of example but not limitation, one or more of a wireless network, a wired network, an internet, an intranet, a public network, a private network, a packet-switched network, a circuit-switched network, an ad hoc network, an infrastructure network, a Public-Switched Telephone Network (PSTN), a cable network, a cellular network, a satellite network, a fiber optic network, or some combination thereof.

In an embodiment, the computing device (104) may include a central processing unit (CPU)/digital signal processor (DSP)/field programmable gate array (FPGA)/electronic application specific integrated circuit (eASIC), or any silicon device where PUSCH/PDSCH bit rate processing (BRP) receiver chain.

In an embodiment, the system (108) may receive an input from the computing device (104) associated with one or more users (102). The input may be based on one or more orthogonal frequency division multiplexing (OFDM) subcarriers transmitted by the computing device (104) via a physical uplink shared channel (PUSCH).

In an embodiment, the system (108) may generate a rate recovered output based on the one or more LLR data bits. The system (108) may generate the rate recovered output by storing the LLR data bits row wise in a buffer and streaming out most significant bit (MSB) LLR data bits across all rows till a limited number of LLR columns are streamed, and the limited number of LLR data bits columns may be based on a modulation order of the one or more IQ data symbols.

In an embodiment, the system (108) may determine one or more in phase and quadrature (IQ) data symbols associated with the one or more OFDM subcarriers.

In an embodiment, the system (108) may generate one or more log likelihood ratio (LLR) data bits based on the one or more IQ data symbols. In an embodiment, the predetermined number of LLR data bits is based on a start offset derived from a low-density parity check (LDPC) base graph and a redundancy version (RV) index associated with the PUSCH processing.

In an embodiment, the predetermined number of LLR data bits may be based on a start offset derived from a LDPC base graph and a RV index associated with the PUSCH processing.

Further in an embodiment, the system (108) may receive an input from a base station (110) associated with one or more users (102). The input may be based on one or more OFDM subcarriers transmitted by the base station (110) via a physical downlink shared channel (PDSCH).

In an embodiment, the system (108) may generate a rate recovered output based on the one or more LLR data bits. The system (108) may generate the rate recovered output by storing the LLR data bits row wise in a buffer and streaming out MSB LLR data bits across all rows till a limited number of LLR columns are streamed, and the limited number of LLR data bits columns may be based on a modulation order of the one or more IQ data symbols.

In an embodiment, the system (108) may determine one or more in phase and quadrature (IQ) data symbols associated with the one or more OFDM subcarriers.

In an embodiment, the system (108) may generate one or more LLR data bits based on the one or more IQ data symbols.

In an embodiment, the system (108) may utilize only a predetermined number of LLR data bits associated with the one or more LLR data bits for decoding at the UE (102). In an embodiment, the predetermined number of LLR data bits may be based on a start offset derived from a LDPC base graph and a RV index associated with the PDSCH processing.

Although FIG. 1 shows exemplary components of the network architecture (100), in other embodiments, the network architecture (100) may include fewer components, different components, differently arranged components, or additional functional components than depicted in FIG. 1. Additionally, or alternatively, one or more components of the network architecture (100) may perform functions described as being performed by one or more other components of the network architecture (100).

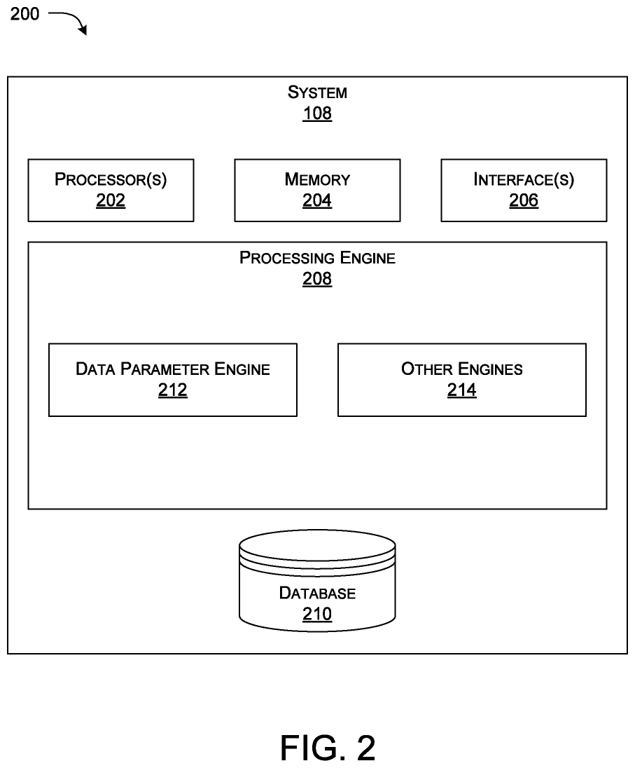

FIG. 2 illustrates an example block diagram (200) of a proposed system (108), in accordance with an embodiment of the present disclosure.

Referring to FIG. 2, the system (108) may comprise one or more processor(s) (202) that may be implemented as one or more microprocessors, microcomputers, microcontrollers, digital signal processors, central processing units, logic circuitries, and/or any devices that process data based on operational instructions. Among other capabilities, the one or more processor(s) (202) may be configured to fetch and execute computer-readable instructions stored in a memory (204) of the system (108). The memory (204) may be configured to store one or more computer-readable instructions or routines in a non-transitory computer readable storage medium, which may be fetched and executed to create or share data packets over a network service. The memory (204) may comprise any non-transitory storage device including, for example, volatile memory such as random-access memory (RAM), or non-volatile memory such as erasable programmable read only memory (EPROM), flash memory, and the like.

In an embodiment, the system (108) may include an interface(s) (206). The interface(s) (206) may comprise a variety of interfaces, for example, interfaces for data input and output (I/O) devices, storage devices, and the like. The interface(s) (206) may also provide a communication pathway for one or more components of the system (108). Examples of such components include, but are not limited to, processing engine(s) (208) and a database (210), where the processing engine(s) (208) may include, but not be limited to, a data ingestion engine (212) and other engine(s) (214). In an embodiment, the other engine(s) (214) may include, but not limited to, a data management engine, an input/output engine, and a notification engine.

In an embodiment, the processing engine(s) (208) may be implemented as a combination of hardware and programming (for example, programmable instructions) to implement one or more functionalities of the processing engine(s) (208). In examples described herein, such combinations of hardware and programming may be implemented in several different ways. For example, the programming for the processing engine(s) (208) may be processor-executable instructions stored on a non-transitory machine-readable storage medium and the hardware for the processing engine(s) (208) may comprise a processing resource (for example, one or more processors), to execute such instructions. In the present examples, the machine-readable storage medium may store instructions that, when executed by the processing resource, implement the processing engine(s) (208). In such examples, the system (108) may comprise the machine-readable storage medium storing the instructions and the processing resource to execute the instructions, or the machine-readable storage medium may be separate but accessible to the system (108) and the processing resource. In other examples, the processing engine(s) (208) may be implemented by electronic circuitry.

In an embodiment, the processor (202) may receive an input via the data ingestion engine (212). The input may be received from a computing device (104) associated with one or more users (102). The processor (202) may store the input in the database (210). The input may be based on OFDM subcarriers transmitted by the computing device (104) via a PUSCH.

In an embodiment, the processor (202) may generate a rate recovered output based on the one or more LLR data bits. The processor (202) may generate the rate recovered output by storing the LLR data bits row wise in a buffer and streaming out MSB LLR data bits across all rows till a limited number of LLR columns are streamed, and the limited number of LLR data bits columns may be based on a modulation order of the one or more IQ data symbols.

In an embodiment, the processor (202) may determine one or more IQ data symbols associated with the one or more OFDM subcarriers.

In an embodiment, the processor (202) may generate one or more LLR data bits based on the one or more IQ data symbols.

In an embodiment, the processor (202) may utilize only a predetermined number of LLR data bits associated with the one or more LLR data bits for each of the one or more IQ data symbols for decoding at the base station. In an embodiment, the predetermined number of LLR data bits may be based on a start offset derived from a LDPC base graph and a RV index associated with the PUSCH processing.

In an embodiment, the processor (202) may receive an input via the data ingestion engine (212), which may be based on one or more OFDM subcarriers transmitted by the base station (110) via a physical downlink shared channel (PDSCH).

In an embodiment, the processor (202) may generate a rate recovered output based on the one or more LLR data bits. The processor (202) may generate the rate recovered output by storing the LLR data bits row wise in a buffer and streaming out MSB LLR data bits across all rows till a limited number of LLR columns are streamed, and wherein the limited number of LLR data bits columns is based on a modulation order of the one or more IQ data symbols.

In an embodiment, the processor (202) may determine one or more in IQ data symbols associated with the one or more OFDM subcarriers.

In an embodiment, the processor (202) may generate one or more LLR data bits associated with the base station (110) based on the one or more IQ data symbols. In an embodiment, the processor (202) may utilize only a predetermined number of LLR data bits associated with the one or more LLR data bits for decoding at the UE (102). The predetermined number of LLR data bits may be based on a start offset derived from a LDPC base graph and a RV index associated with the PDSCH processing.

Although FIG. 2 shows exemplary components of the system (108), in other embodiments, the system (108) may include fewer components, different components, differently arranged components, or additional functional components than depicted in FIG. 2. Additionally, or alternatively, one or more components of the system (108) may perform functions described as being performed by one or more other components of the system (108).

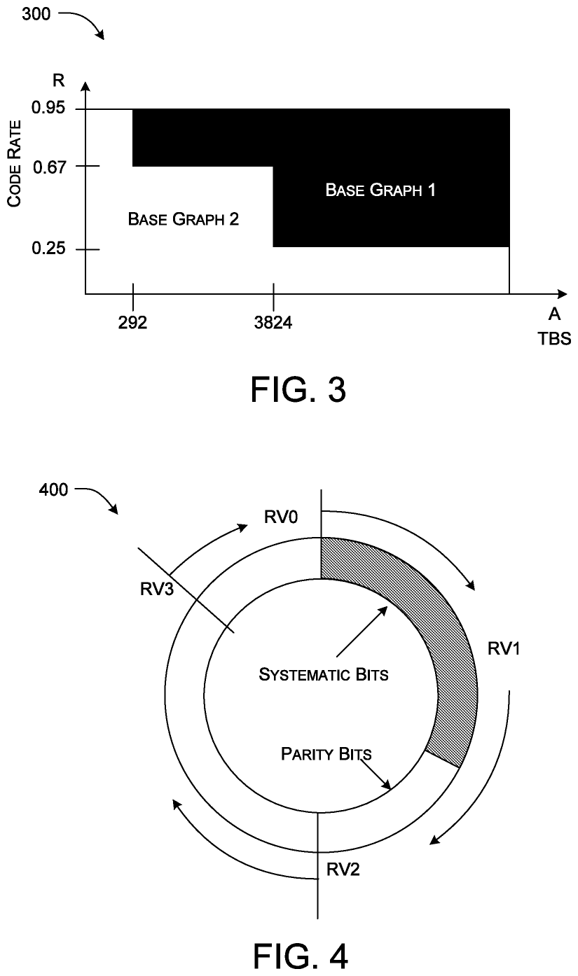

FIG. 3 illustrates an example block diagram (300) of a base graph selection during channel coding, in accordance with an embodiment of the present disclosure.

As illustrated in FIG. 3, channel coding may be applied individually to each segment. Restricting the code block size handled by the channel coding algorithm may limit the encoding complexity at the UE (102). Base graph selection may use a combination of coding rate and transport block size thresholds. Base Graph 2 may be selected if the target coding rate is less than 0.25, or if the transport block size is less than 292 bits, or if the transport block size is less than 3824 bits and the target coding rate is less than 0.67 otherwise, base graph I may be selected. The output from channel coding may be forwarded to a Rate Matching function. The Rate Matching function may process each channel coded segment separately. Rate Matching may be completed via a bit selection process and a bit interleaving process. As a precursor to the two stages, filler bits may be added to align code block lengths as per standards may be removed.

Further, bit selection process reduces or repeats the number of channel coded bits to match the capacity of the allocated air-interface resources. Bit selection extracts ‘E’ bits from the LDPC encoded code block bit-stream present in a circular buffer of size N. The size of the circular buffer may have a dependency upon the UE capability as well. Limited Buffer Rate Matching (LBRM) is a feature to cater to devices which have a limited capacity for buffering large code blocks.

FIG. 4 illustrates an example block diagram (400) of a bit selection process, in accordance with an embodiment of the present disclosure.

As illustrated in FIG. 4, the bit selection process may extract a subset of bits from the circular buffer using a specific starting position. The starting position may depend upon the Redundancy Version (RV). RV0, RV1 and RV2 have starting positions which are 0, 25 and 50% around the circular buffer. RV3 may have a starting position which is ˜85% around the circular buffer. The starting position for RV3 may be moved towards the starting position for RV0 to increase the number of systematic bits which are captured by an RV3 transmission. This approach may be adopted to allow self-decoding when either RV0 or RV3 is transmitted, i.e. the receiver can decode the original transport block after receiving only a single standalone transmission of RV0 or RV3. RV I and RV2 do not allow self-decoding. These RV require another transmission using a different RV to allow decoding of the transport block.

Further, bit interleaving may be applied once the set of bits have been extracted from the circular buffer. Bit Interleaving may involve the stream of bits being read into a table row-by-row, and then being read out of the table column-by-column. The number of rows belonging to the table may be set equal to a modulation order and each column may correspond to a single modulation symbol.

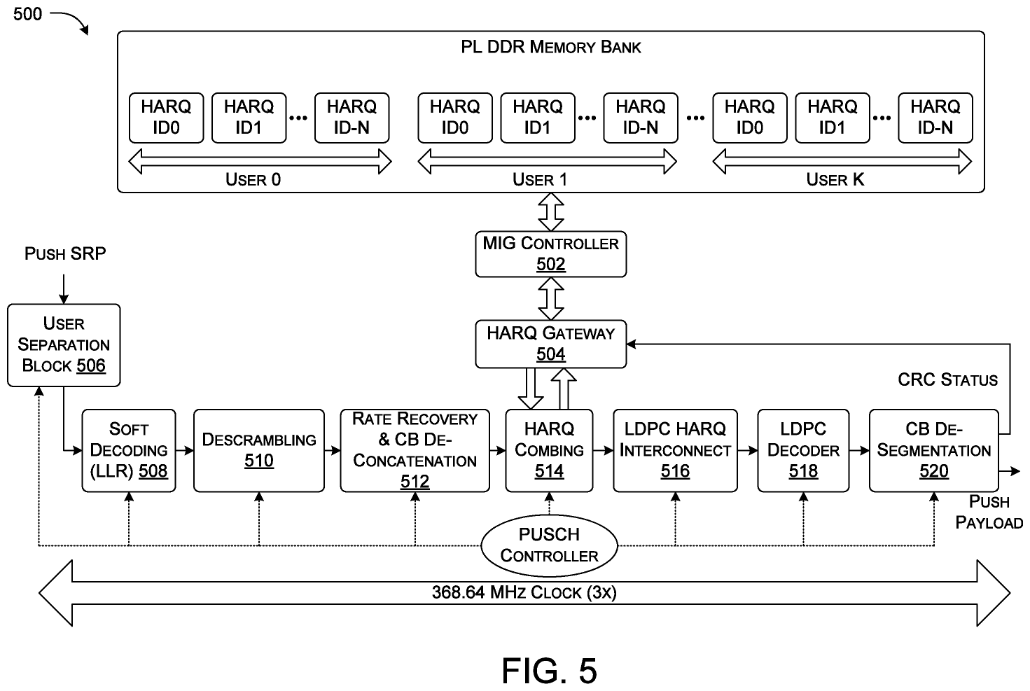

FIG. 5 illustrates an example architecture diagram (500) of bit rate processing in a physical uplink shared channel (PUSCH) receiver with optimized rate recovery and hybrid automatic repeat request (HARQ) combining, in accordance with an embodiment of the present disclosure.

In an embodiment, the rate recovery and HARQ combining process in a PUSCH may require large memory buffers to store and process the input data. The maximum number of input data that needs to be processed depends on the Resource allocation (nRE), number of layers (nLayers) and Modulation Order (Qm). Maximum allowed channel bandwidths for FR1 and FR2 in may include 100 MHz and 400 MHz respectively for a single carrier. As an illustration, FR1 may include maximum numbers of physical resource blocks (PRBs). In fifth generation (5G) new radio (NR), each time a domain slot may include 14 symbols. Additionally, standards have also specified the maximum number of resource elements (REs) per slot per PRB to be 156. Hence, any user provided with full resource allocation may at maximum be allocated with 156 REs per PRB and 273 PRBs per slot which equals 42588 REs per slot. Therefore, number of LLRs (G) received at the input of a Rate Recovery module may be derived using following formula:

G=nLayers*nRE*Qm*numCodeword

In an embodiment, considering the system (108) with nLayers <=4 as an example here, a number of code words may be restricted to 1. Hence, a maximum value of G may be corresponding to nLayers=4, nRE=42588 and Qm=8 (8 bits per symbol using 256 QAM). This equates to 1,362,816 LLRs. Assuming each LLR may be represented using 8 bits fixed point format, maximum number of input bits received at the input of rate recovery block may be 10,902,528 bits which may be approximately 10 Gigabytes (GB).

In an embodiment, for incremental redundancy based HARQ, the process of combining output from a previous transmission (N bit) with the present retransmission input may depend upon a StartOffset. The StartOffset may vary based on a Redundancy Version (RV). To achieve this type of combining process with less processing cycle, the rate recovery block may stream the output by considering the StartOffset.

Further, in an embodiment, a Low Density Parity Check (LDPC) coding for the PUSCH may be specified. The LDPC may be selected as an alternative to Turbo coding used for the PUSCH in 4G. The LDPC channel coding may be characterized by its sparse parity check matrix. This means that the matrix used to generate the set of parity bits may include a relatively small number of I's, i.e. a Low Density of I's. The Low Density characteristic may help to reduce the complexity of both encoding and decoding. Reduced complexity may translate to lower power consumption and a smaller area of silicon. The LDPC solution selected may be scalable to support a wide range of code block sizes and a wide range of coding rates. LDPC and Turbo coding may offer similar performance in terms of their error correction capabilities. The soft combined code blocks may be fed to LDPC decoder through a LDPC HARQ interconnect block. The LDPC HARQ interconnect block may ensure of providing extra 2Zc samples at the start of each code block as per the requirement of Xilinx LDPC decoder. The decoded samples from LDPC decoder may be checked for cyclic redundancy check (CRC) by the CRC decode block which may pass the final transport block to a functional application programme interface (FAPI) parser along with a CRC status.

As illustrated in FIG. 5, in an embodiment, implementation of optimized rate recovery and HARQ Combining method for PUSCH bit rate processing chain on a Xilinx ZCU111 FPGA chip may be explained. In this chip, main memory component may be Block random access memory (BRAM) where each 36 Kilo (K) size BRAM may store 36 Kilobytes (Kb) data.

In an embodiment, inputs may be received from various users (102) (User 0 . . . . User K). The input may be processed by a memory interface generator (MIG) controller (502) and a HRQ gateway (504). The PUSCH controller (506) may include various processes that may include but not limited to PUSCH service redundancy protocol (SRP) processing by a user separation block (508) followed by soft decoding (510), descrambling (512), rate recovery (514), code block (CB) con-catenation (516), HARQ combining (518), LDPC HARQ interconnect (520), decoding by a LDPC decoder (522) and CB de-segmentation (524). Output from the CB de-segmentation (524) may be provided to a PUSCH payload while a CRC status may be provided to the HARQ gateway (504).

In an embodiment, channel estimation may be used by the system (108) to equalize (reverse the imperfections induced by a wireless channel as much as possible) of PUSCH data symbols. Although channel estimated output may have a resemblance to the original In phase and quadrature phase (IQ constellation) diagram transmitted by a transmitter, the channel estimated output may include bit errors which to be corrected by a bit rate processing stage. Equalized IQ data may be then stored in a buffer from where the user separation block (502) may select equalized IQ samples for a particular user. Equalized data for a particular user is converted from Complex IQ samples (typically represented using 32 bits) to LLR.

In an embodiment, a QAM demodulator block may demodulate complex data symbols to data bits or LLR values based on the modulation types supported by 5G NR standard. The LLR block may perform demodulation assuming the input constellation power normalization is in accordance with NR standard. The normalization values may be based on the modulation type.
1/√2 for BPSK, QPSK, and pi/2-BPSK
1/√10 for 16-QAM
1/√42 for 64-QAM
1/√170 for 256-QAM

In an embodiment, there may be two types of decoding i.e. hard decision decoding and soft decision decoding. Soft decoding may de-map data symbols to LLR values. The LLR value for each bit may indicate how likely the bit is 1 or 0. Further, hard decoding may de-map data symbols to bits 1 or 0.

In an embodiment, the LLR block/soft decoding block (504) may perform soft demodulation of the data symbols and may be designed to work on four different modulation techniques i.e. QPSK, 16 QAM, 64 QAM and 256 QAM. Each input to the block may carry 48 bit and it contains channel state information (CSI) bits along with data bits. Each output sample width may depend on the QAM order and maximum width of the output can be 64 bits. The LLR Block (504) may be designed to give soft output bits depending on the QAM order and the subsequent blocks (Descrambler and Rate Recovery) may process the input bits based on the QAM order. For QPSK IQ symbol, the LLR block (504) may pack 2 LLRs (2×8 bits per LLR) in the MSB of the 64 bit output of LLR block. Similarly, IQ samples corresponding to 16 QAM, 64 QAM and 256 QAM may pack 4 LLRs (32 bits), 6 LLRs (48 bits) and 8 LLRs (64 bits) respectively. These packed LLRs may be then processed by the descrambling block (506).

In an embodiment, the general way of descrambling may include changing the sign of the soft bit after LLR demodulation. The de-scrambling operation may not change the order of the bits. Instead, the de-scrambling operation may switch some of the 1's into 0's and some of the 0's into 1's. The switching may be performed using a modular two summation between an original bit stream and a pseudo random sequence. De-scrambling may include reducing interference between adjacent cells to randomize the interference signal.

In an embodiment, the input data to the de-scrambling block (506) be received from the soft decoder as 64 bits (8 soft LLR bits), 48 bits (6 soft LLR bits), 32 bits (4 soft LLR bits) or 16 bits (2 soft LLR bits) for Qm order (QAM modulation order) 8 (256QAM), 6 (64QAM), 4 (16QAM) or 2 (QPSK) respectively. Other than QAM order, de-scrambling process is controlled by parameters G_d, Descrambling identification (ID) and radio network temporary identifier (RNTI). Two 31 bit integers may be used as a linear feedback shift registers (LFSRs) and may be shifted accordingly using left/right shifting operators to meet the timing specifications. A pseudo-noise (PN) sequence generator may be designed to provide 8 bits of PN sequence for processing 64 bits (maximum) of data per cycle. For descrambling, the same PN sequence may be generated in a similar way for a scrambling process. The Descrambled sequence may be described as Y, where

$$Y = LLR * ( 1 - 2 c )$$

The formula 1-2c (where c may be 0 or 1 i.e. PN sequence data) may be used to make positive and negative sign changes to the LLR. If symbol generated from PN sequence is 1, the polarity of the incoming byte of data may be reversed and if the symbol is 0, data may be bypassed.

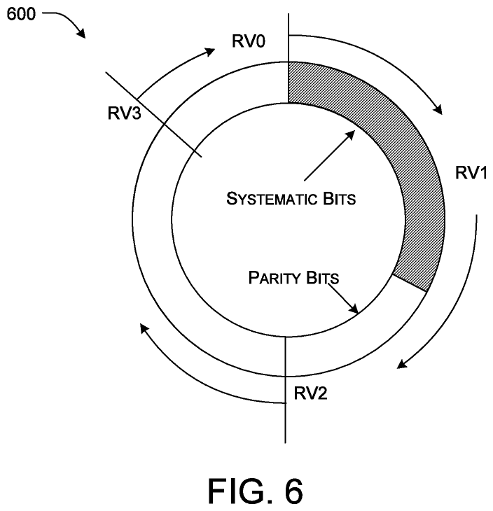

FIG. 6 illustrates an example block diagram (400) of a bit selection process of the PUSCH receiver incorporating optimized rate recovery and HARQ combining, in accordance with an embodiment of the present disclosure.

As illustrated in FIG. 6, in an embodiment, rate recovery in the receiver side may perform exactly the reverse of the process done in the transmitter side. Hence, for channel decoding base graph selection and code block de-concatenation may be performed. CB de-concatenation may be achieved as per standards in order to do further processing code block wise.

In an embodiment, the optimized rate recovery block input may receive 64 bit wide data input from the de-scrambler (for highest QAM order 256 all 64 bits data will be valid). Each code block data may be bit de-interleaved initially. De-interleaving may be performed by using only a single buffer which includes enough storage capacity to store maximum data input for a code block. Since, for 64-bit wide data input, packing LLRs may depend on Qm order. Considering the length of data input per code block to by E and maximum value of E to be Emax (corresponding to the least MCS index having maximum repetitions, hence Qm may always be 2 for Emax), size of the buffer may be derived as Emax/2 (Each data input will have 2 LLRs for Qm=2). Thus dimension of the buffer may be represented as a BRAM storage having (Emax/2) number of row elements and 1 column element i.e., (Emax/2)×1 vector.

In an embodiment, actual data received from the de-scrambler may be stored in the buffer as (E/Qm)×1 vector. Since each data input may include have Qm number of LLRs, stored data may be viewed as (E/Qm)×Qm vector where each LLR stored may be assumed as column of the vector. Further, the de-interleaving process may be simplified due to a read operation on the 1^{st} MSB LLR (1^{st} column) of each data input up to E/Qm rows, then 2^{nd} MSB LLR (2^{nd} column) and so on till Qm number of LLR columns are read out.

In an embodiment, for bit-selection and filler bit addition stages, the value of startOffset, size (numf) and position of filler bits (numk) may be calculated on the basis of RV index, and target code rate. The numk (filler bits position index) and numf (number of filler bits that will be added in each code block) may be managed according to the StartOffset for different RV. The rate recovery block may be designed to process the input bits according to StartOffset and the output may be streamed in the same manner. Depending on target code rate, E may be greater than N (LDPC Codeword size) for lesser code rates or E can be lesser than N for higher code rates. For higher code rates E may be as less than one-third of the N. Hence to improve processing latency, the rate recovery block may send out an indication dataLength to the HARQ combining block which indicates that the rate recovery block may stream out only dataLength number of LLRs to the HARQ combining block. This step may reduce processing latency as well as power consumption, since HARQ combining may be done only on dataLength number of LLRS instead of complete N sized LLRs that happen conventionally.

In an embodiment, in Incremental redundancy type of HARQ, each retransmission may be identical. Whenever a retransmission is required, the retransmission typically may use a different set of coded bits than the previous transmission. The receiver may combine the retransmission with the previous transmission attempts of the same packet. Based on a low-rate code the different redundancy versions (RV) may be generated by puncturing the output of the encoder. In the first transmission only, a limited number of bits may be transmitted, effectively leading to a high-rate code. In the retransmission, additional coded bits may be transmitted. Instead of the HARQ combining block being non-functional in conventional designs, the HARQ combining block described in the present disclosure may be provided with intelligence to restrict combining to only dataLength number of LLRs and also aligning the input coming from the rate recovery block according to the StartOffset.

In an embodiment, the StartOffset for different RVs 0, 2, 3 and 1 may be 0, 33*Zc, 56*Zc and 17*Zc respectively for base graph 1 and 0, 25*Zc, 43*Zc and 0, 25*Zc respectively for base graph 2. The previous RV output stored in the double data rate (DDR) memory may be loaded combined with the rate recovery output. The proposed rate recovery and HARQ combining block may reuse the memory buffer for each code block to reduce the memory consumption.

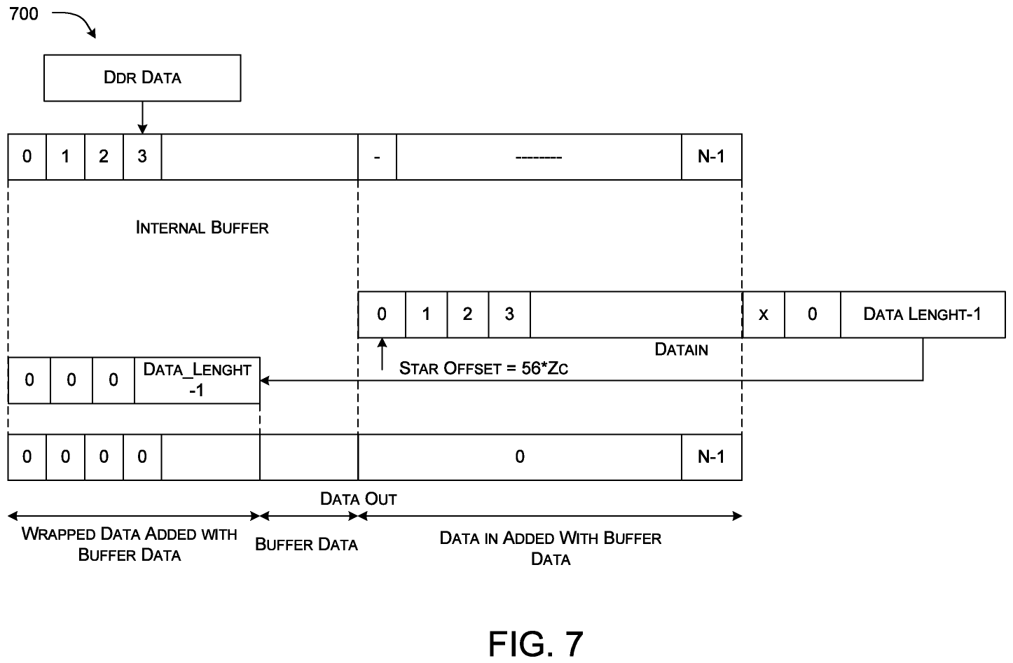

FIG. 7 illustrates an example block diagram (700) of the HARQ buffer, in accordance with an embodiment of the present disclosure.

As illustrated in FIG. 7, in an embodiment, the HARQ gateway may maintain the DDR bank for storing soft bits corresponding to multiple users (Maximum 50 active users) where each user (102) may have multiple HARQ process IDs (Maximum process IDs 4). Further, the PUSCH chain may support HARQ combining using incremental redundancy and support all 4 possible RVs. A transmission may be considered a new transmission when the transmission is first ever received for this process ID with RV index 0 and network device interface (NDI) is 1 in HARQ control information. Otherwise, the transmission may be considered as the retransmission. For the new transmission, the HARQ process may replace the old contents of associated HARQ buffer in the DDR bank with new contents. If the decoding of this data block is successful, then the data may be handed over to L2 and the current HARQ memory session may be cleared. If decoding fails, then the data may be preserved in the HARQ buffer. In case of retransmission, the retransmitted data may be soft combined with the old buffer contents by HARQ combining block in order to increase the decoding probability and improve the system performance.

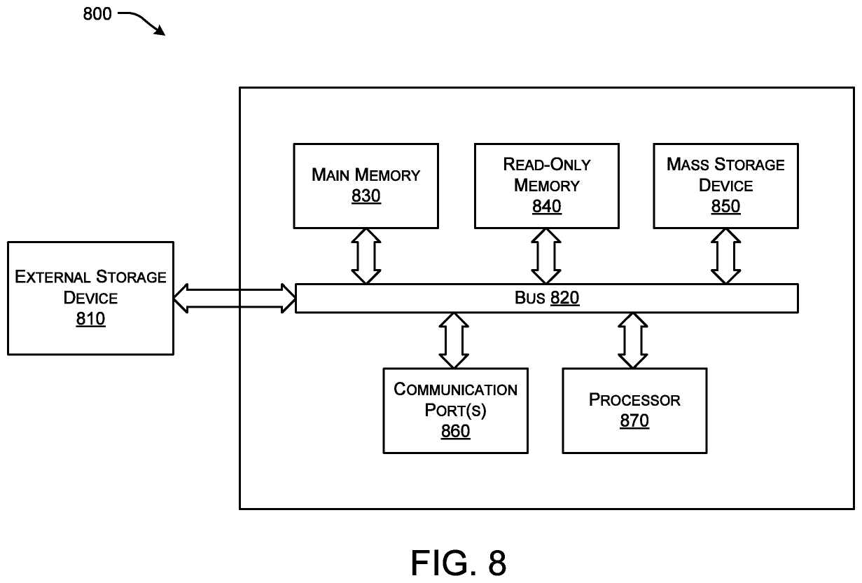

FIG. 8 illustrates an exemplary computer system (800) in which or with which embodiments of the present disclosure may be implemented.

As shown in FIG. 8, the computer system (800) may include an external storage device (810), a bus (820), a main memory (830), a read-only memory (840), a mass storage device (850), a communication port(s) (860), and a processor (870). A person skilled in the art will appreciate that the computer system (800) may include more than one processor and communication ports. The processor (870) may include various modules associated with embodiments of the present disclosure. The communication port(s) (860) may be any of an RS-232 port for use with a modem-based dialup connection, a 10/100 Ethernet port, a Gigabit or 10 Gigabit port using copper or fiber, a serial port, a parallel port, or other existing or future ports. The communication ports(s) (860) may be chosen depending on a network, such as a Local Area Network (LAN), Wide Area Network (WAN), or any network to which the computer system (800) connects.

In an embodiment, the main memory (830) may be Random Access Memory (RAM), or any other dynamic storage device commonly known in the art. The read-only memory (840) may be any static storage device(s) e.g., but not limited to, a Programmable Read Only Memory (PROM) chip for storing static information e.g., start-up or basic input/output system (BIOS) instructions for the processor (870). The mass storage device (850) may be any current or future mass storage solution, which can be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces).

In an embodiment, the bus (820) may communicatively couple the processor(s) (870) with the other memory, storage, and communication blocks. The bus (820) may be, e.g. a Peripheral Component Interconnect PCI)/PCI Extended (PCI-X) bus, Small Computer System Interface (SCSI), (USB), or the like, for connecting expansion cards, drives, and other subsystems as well as other buses, such a front side bus (FSB), which connects the processor (870) to the computer system (800).

In another embodiment, operator and administrative interfaces, e.g., a display, keyboard, and cursor control device may also be coupled to the bus (820) to support direct operator interaction with the computer system (800). Other operator and administrative interfaces can be provided through network connections connected through the communication port(s) (860). Components described above are meant only to exemplify various possibilities. In no way should the aforementioned exemplary computer system (800) limit the scope of the present disclosure.

In an embodiment, although exemplary implementations have been illustrated for a PUSCH BRP chain receiver at the network end, same holds true in all essence for a PDSCH BRP chain receiver implementation at the UE end as well.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter is to be implemented merely as illustrative of the disclosure and not as a limitation.

### Advantages of the Invention

The present disclosure provides a system and a method using an optimized rate recovery and a hybrid automatic repeat request (HARQ) combining method for a physical uplink shared channel (PUSCH) and a physical downlink shared channel (PDSCH) bit rate processing chains.

The present disclosure provides a system and a method where LLR soft-bits are efficiently packed in a way that for each Equalized IQ symbol, Qm number of LLRs are packed from MSB to LSB in a storage element.

The present disclosure provides a system and a method to de-interleave LLRs received from a de-scrambler in the Rate Recovery stage by storing bit-packed LLRs row wise in a buffer and reading out most significant bit (MSB) LLRs across all rows till the limited number of LLR columns (equal to the modulation order) have been read out.

The present disclosure provides a system and a method that uses only a data length number of LLRs during the HARQ combining stage to reduce latency and power consumption.

The present disclosure provides a system and a method where the data length number of LLRs processed by the HARQ block are based on a start offset derived from base graph and RV index.

The present disclosure provides a system and a method where a single buffer is used for all three rate recovery sub stages, including a de-interleaving stage, a bit-deselection stage, and a filler bit addition stage for the PUSCH and the PDSCH bit rate processing chains.

The present disclosure provides a system and a method where the data length number of LLRs during the HARQ combining stage instead of full ‘N’ number of LLRs in the PUSCH and the PDSCH bit rate processing chains reduces latency and power consumption.

We claim:

1. A system (108) for optimized memory utilization during uplink data decoding at a base station, the system (108) comprising:
a processor (202); and
a memory (204) operatively coupled with the processor (202), wherein said memory (204) stores instructions which, when executed by the processor (202), cause the processor (202) to:
receive an input from a computing device (104) associated with one or more users (102), wherein the input is based on one or more orthogonal frequency division multiplexing (OFDM) subcarriers transmitted by the computing device (104) via a physical uplink shared channel (PUSCH);
determine one or more in phase and quadrature (IQ) data symbols associated with the one or more OFDM subcarriers;
generate one or more log likelihood ratio (LLR) data bits associated with the computing device (104) based on the one or more IQ data symbols; and
utilize a predetermined number of LLR data bits associated with the one or more LLR data bits for each of the one or more IQ data symbols for optimized memory utilization.

2. The system (108) as claimed in claim 1, wherein the predetermined number of LLR data bits is based on a start offset derived from a low-density parity check (LDPC) base graph and a redundancy version (RV) index associated with the PUSCH processing.

3. The system (108) as claimed in claim 1, wherein the processor (202) is to generate a rate recovered output based on the one or more LLR data bits.

4. The system (108) as claimed in claim 3, wherein the processor (202) is to generate the rate recovered output by storing the LLR data bits row wise in a buffer and streaming out most significant bit (MSB) LLR data bits across all rows till a limited number of LLR columns are streamed, and wherein the limited number of LLR data bits columns is based on a modulation order of the one or more IQ data symbols.

5. A method for optimized memory utilization during an uplink data decoding at a base station, the method comprising:
receiving, by a processor (202) associated with a system (108), an input from a computing device (104) associated with one or more users (102), wherein the input is based on one or more orthogonal frequency division multiplexing (OFDM) subcarriers transmitted by the computing device (104) via a physical uplink shared channel (PUSCH);
determining, by the processor (202), one or more in phase and quadrature (IQ) data symbols associated with the one or more OFDM subcarriers;
generating, by the processor (202), one or more log likelihood ratio (LLR) data bits associated with the computing device (104) based on the one or more IQ data symbols; and
utilizing, by the processor (202), a predetermined number of LLR data bits associated with the one or more LLR data bits for each of the one or more IQ data symbols for optimized memory utilization.

6. The method as claimed in claim 5, wherein the predetermined number of LLR data bits is based on a start offset derived from a low-density parity check (LDPC) base graph and a redundancy version (RV) index associated with the PUSCH processing.

7. The method as claimed in claim 5, comprising generating, by the processor (202), a rate recovered output based on the one or more LLR data bits.

8. The method as claimed in claim 7, comprising generating, by the processor (202), the rate recovered output by storing the LLR data bits row wise in a buffer and streaming out most significant bit (MSB) LLR data bits across all rows till a limited number of LLR columns are streamed, and wherein the limited number of LLR data bits columns is based on a modulation order of the one or more IQ data symbols.

9. A non-transitory computer readable medium comprising a processor with executable instructions, causing the processor to:
receive an input from a computing device (104) associated with one or more users (102), wherein the input is based on one or more orthogonal frequency division multiplexing (OFDM) subcarriers transmitted by the computing device (104) via a physical uplink shared channel (PUSCH);
determine one or more in phase and quadrature (IQ) data symbols associated with the one or more OFDM subcarriers;
generate one or more log likelihood ratio (LLR) data bits associated with the computing device (104) based on the one or more IQ data symbols; and
utilize a predetermined number of LLR data bits associated with the one or more LLR data bits for each of the one or more IQ data symbols for optimized memory utilization.

10. A user equipment (UE) for optimized memory utilization, the system (108) comprising:
a processor; and
a memory operatively coupled with the processor, wherein said memory stores instructions which, when executed by the processor, cause the processor to:
receive an input from a base station associated with one or more users, wherein the input is based on one or more orthogonal frequency division multiplexing (OFDM) subcarriers transmitted by the base station via a physical downlink shared channel (PDSCH);
determine one or more in phase and quadrature (IQ) data symbols associated with the one or more OFDM subcarriers;
generate one or more log likelihood ratio (LLR) data bits based on the one or more IQ data symbols; and
utilize a predetermined number of LLR data bits associated with the one or more LLR data bits for each of the one or more IQ data symbols for optimized memory utilization.

11. The UE as claimed in claim 10, wherein the predetermined number of LLR data bits is based on a start offset derived from a low-density parity check (LDPC) base graph and a redundancy version (RV) index associated with the PDSCH processing.

12. The UE as claimed in claim 10, wherein the processor (202) is to generate a rate recovered output based on the one or more LLR data bits.

13. The UE as claimed in claim 12, wherein the processor is to generate the rate recovered output by storing the LLR data bits row wise in a buffer and streaming out most significant bit (MSB) LLR data bits across all rows till a limited number of LLR columns are streamed, and wherein the limited number of LLR data bits columns is based on a modulation order of the one or more IQ data symbols.

14. A method for optimized memory utilization during a downlink data decoding at a user equipment (UE), the method comprising:
receiving, by a processor (202), an input from a base station (110) associated with one or more users (102), wherein the input is based on one or more orthogonal frequency division multiplexing (OFDM) subcarriers transmitted by the computing device (104) via a physical downlink shared channel (PDSCH);
determining, by the processor (202), one or more in phase and quadrature (IQ) data symbols associated with the one or more OFDM subcarriers;
generating, by the processor (202), one or more log likelihood ratio (LLR) data bits associated with the base station (110) based on the one or more IQ data symbols; and
utilizing, by the processor (202), a predetermined number of LLR data bits associated with the one or more LLR data bits for each of the one or more LLR data bits for optimized memory utilization.
